(19) United States
(12) Patent Application Publication
(10) Pub. No.: US 2008/0002801 A1
(43) Pub. Date: Jan. 3, 2008

(54) Fast-settling clock generator

(76) Inventors: Guido Droege, Braunschweig (DE); Uwe Zillmann, Braunschweig (DE)

Correspondence Address: CARRIE A. BOONE, P.C., 1110 NASA PARKWAY, SUITE 450, HOUSTON, TX, 77058, US

(21) Appl. No.: 11/478,268

(22) Filed: Jun. 29, 2006

(51) Int. Cl. H03D 3/24

(52) U.S. Cl. 375/375

(57) ABSTRACT

A clock generator with a fast settling time features a coarse-tuning circuit that is executed a single time, and a fine-tuning circuit that is executed periodically. The fine-tuning circuit sends an analog voltage to a voltage-controlled oscillator (VCO). The coarse-tuning circuit sends a load capacitance parameter to the VCO. The analog voltage and the load capacitance are used to program the VCO, which generates a clock signal. The coarse-tuning circuit and the fine-tuning circuit include registers that store the load capacitance and analog voltage information, respectively, in digital form. When switching of the oscillator occurs, the clock generator quickly produces a clock signal in accordance with the stored digital values.

### TECHNICAL FIELD

The application relates to clock generator circuitry and, more particularly, to a fast-switching clock generator.

### BACKGROUND

A clock generator produces a timing signal, or clock signal, which may be used to synchronize the operation of other circuits associated with the clock generator. The clock generator includes a resonant circuit, such as an oscillator, arranged in a feedback configuration. The output signal produced by the clock generator may be compared with a reference signal, such as in a phase-locked loop (PLL) circuit.

One design consideration with clock generators is the settling time of the circuit. Where the settling time is long, the clock generator achieves a stable clock signal after a relatively long time period. A clock generator with a short settling time achieves the stable clock signal at a much faster rate. Power management-capable systems, for example, may be powered down, or put into a standby mode, such that the clock generator is turned on and off. A clock generator having a slow settling time may be undesirable in such systems.

### BRIEF DESCRIPTION OF THE DRAWINGS

The foregoing aspects and many of the attendant advantages of this disclosure will become more readily appreciated as the same becomes better understood by reference to the following detailed description, when taken in conjunction with the accompanying drawings, wherein like reference numerals refer to like parts throughout the various views, unless otherwise specified.

FIG. 1 is a block diagram of a clock generator, according to some embodiments;

FIG. 2A is a block diagram of the fine-tuning circuit of the clock generator of FIG. 1, according to some embodiments;

FIG. 2B is a block diagram of the coarse-tuning circuit of the clock generator of FIG. 1, according to some embodiments;

FIG. 3 is a flow diagram depicting operation of the clock generator of FIG. 1, according to some embodiments;

FIG. 4 is a detailed block diagram of the clock generator of FIG. 1, according to some embodiments;

FIG. 5 is a voltage-frequency graph illustrating the coarse-tuning and fine-tuning of the clock generator of FIG. 1, according to some embodiments;

FIG. 6 is a block diagram of a clock generator, according to some embodiments; and

FIG. 7 is a block diagram of a processor-based system using the clock generator of FIG. 1, according to some embodiments.

### DETAILED DESCRIPTION

In accordance with the embodiments described herein, a clock generator is disclosed, having a fast settling time, relative to prior art PLLS. The clock generator features a coarse-tuning circuit that is executed a single time and a fine-tuning circuit that is executed periodically. The fine-tuning circuit sends an analog voltage to a voltage-controlled oscillator (VCO). The coarse-tuning circuit sends a load capacitance parameter to the VCO. The analog voltage and the load capacitance are used to program the VCO, which generates a clock signal. The coarse-tuning circuit and the fine-tuning circuit include registers that store the load capacitance and analog voltage information, respectively, in digital form. When switching of the oscillator occurs, the clock generator quickly produces a clock signal in accordance with the stored digital values.

In the following detailed description, reference is made to the accompanying drawings, which show by way of illustration specific embodiments in which the described subject matter may be practiced. However, it is to be understood that other embodiments will become apparent to those of ordinary skill in the art upon reading this disclosure. The following detailed description is, therefore, not to be construed in a limiting sense, as the scope of the present disclosure is defined by the claims.

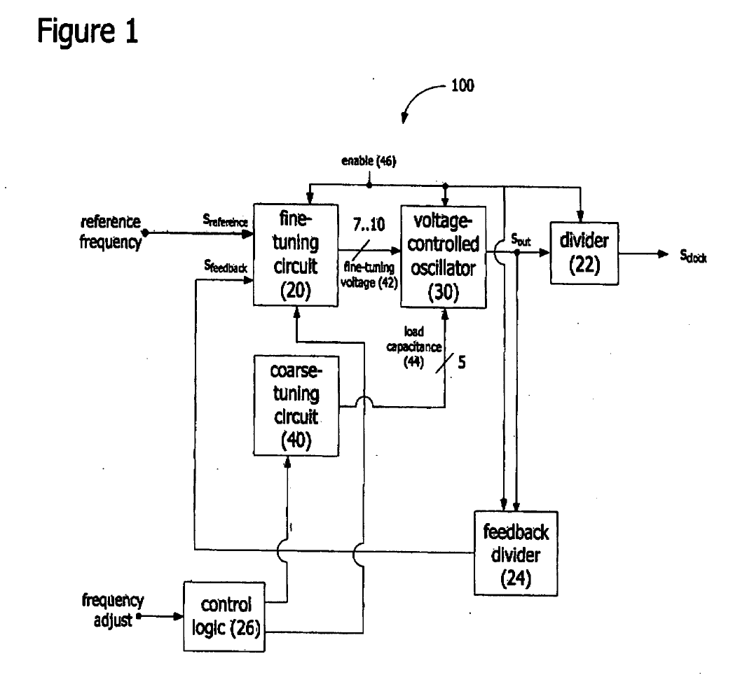

In FIG. 1, a clock generator 100 is depicted, according to some embodiments. The clock generator 100 includes a fine-tuning circuit 20, a coarse-tuning circuit 40, a VCO 30, a divider 22, a feedback divider 24, and control logic 26. The VCO 30 includes an oscillator that generates an output signal, sₒᵤₜ, and, subsequently, a clock signal, s_{clock}. As used herein, the VCO 30 may at times be referred to simply as the oscillator 30, or the oscillator. Part of the output signal, sₒᵤₜ, is fed back through the feedback divider 24, as the signal, s_{feedback}, and part of the output signal is sent through the divider 22, to become the clock signal, s_{clock}. The feedback signal, s_{feedback}, as well as a reference signal, s_{reference}, are fed into the fine-tuning circuit 20.

As the name suggests, the voltage-controlled oscillator 30 is an oscillator that is adjusted upon receiving an analog voltage. As the analog voltage increases, the oscillator frequency increases; likewise, as the analog voltage decreases, the oscillator frequency decreases. The VCO 30 also includes an adjustable load capacitor (not shown), which may be fed a digital value to control the capacitance. This, in turn, controls the frequency of the oscillator. Using these two parameters, the analog voltage and the load capacitance, the frequency of the clock signal, s_{clock}, may be controlled.

The VCO 30 produces the clock signal, s_{clock}, based upon the analog voltage and the load capacitance parameters received. Part of the clock signal, s_{clock}, is returned to the VCO 30 as the feedback signal, s_{feedback}. In the process of feeding an analog voltage to the VCO 30 that results in the desired clock signal, s_{clock}, the frequency of the signal, s_{clock}, or f_{clock}, may swing above and below a desired frequency. The swing process is known as the settling time of the VCO 30.

In FIG. 1, the fine-tuning circuit 20 generates an analog signal and the coarse-tuning circuit 40 sends a digital value corresponding to a desired load capacitance. Together, these circuits 20 and 40 cause the VCO 30 to produce the desired clock signal, s_{clock}. In some embodiments, the fine-tuning circuit 20 sends a predetermined voltage, known herein as a fine-tuning voltage 42, to the VCO 30. In some embodiments, the coarse-tuning circuit 40 sends a predetermined digital value, known herein as a load capacitance 44, to the VCO 30.

During initialization of the clock generator 100, a frequency adjust request is made to the control logic 26, which activates the fine-tuning circuit 20 and the coarse-tuning circuit 40. In some embodiments, signals transmitted by the control logic 26 are low-speed digital signals. The coarse-tuning circuit 40 sends the load capacitance 44 to the VCO 30; likewise, the fine-tuning circuit 20 sends the fine-tuning voltage 42 to the VCO. The load capacitance 44 and the fine-tuning voltage 42 cause a change in the oscillator, which results in a change in the frequency, fₒᵤₜ, of the output signal, sₒᵤₜ. In some embodiments, the coarse-tuning circuit 40 is executed prior to the fine-tuning circuit 20. The time that it takes for the frequency, fₒᵤₜ, of the output signal, sₒᵤₜ, to become stabilized is known as the settling time of the clock generator 100. In some embodiments, signals transmitted by the control logic 26 are low-speed digital signals.

The clock generator 100 includes two dividers: a forward divider 22 and a feedback divider 24, which is part of a feedback loop. In some embodiments, the feedback divider 24 is reset before the fine-tuning circuit 24 is executed. The reset of the feedback divider 24 mitigates the possibility of a long settling time for phase alignment between the divided signal, s_{feedback}, and the reference signal, s_{reference}.

An enable signal 46 is shown coupled to both the VCO 30 and to the fine-tuning circuit 20. The enable signal 46 controls the VCO 30, since the VCO uses more power than the other devices. The fine-tuning circuit 20, the divider 22, and the feedback divider 24 may be enabled/disabled as well.

As used herein, the term “switching” refers to any time the input signal into the clock generator changes. For the clock generator 100, a change in the feedback signal, s_{feedback}, is considered switching of the clock generator. Switching may occur, for example, when power to the clock generator 100 is disabled, such as when the system enters a standby mode; switching again occurs when power to the clock generator 100 is enabled (enable signal 46). The settling time of a clock generator refers to a time period between when the input signal into the clock generator changes and a stable output signal (e.g., s_{clock}), is produced.

In some embodiments, the clock generator 100 is characterized by a fast settling time. In other words, the clock signal, s_{clock}, quickly settles to its steady-state frequency, f_{clock}, following enablement of the input. In some embodiments, the settling time of the clock generator 100 is 100 nanoseconds (ns) or less. The clock generator 100 is thus capable of settling efficiently. For example, the clock generator 100 may be part of a power management system. A typical phase-locked loop (PLL) circuit may stabilize somewhere in the range of 1-100 microseconds, slower than the settling time of the clock generator 100. The clock generator 100 is capable of generating a stable clock signal, s_{clock}, with greater efficiently than typical PLL circuits.

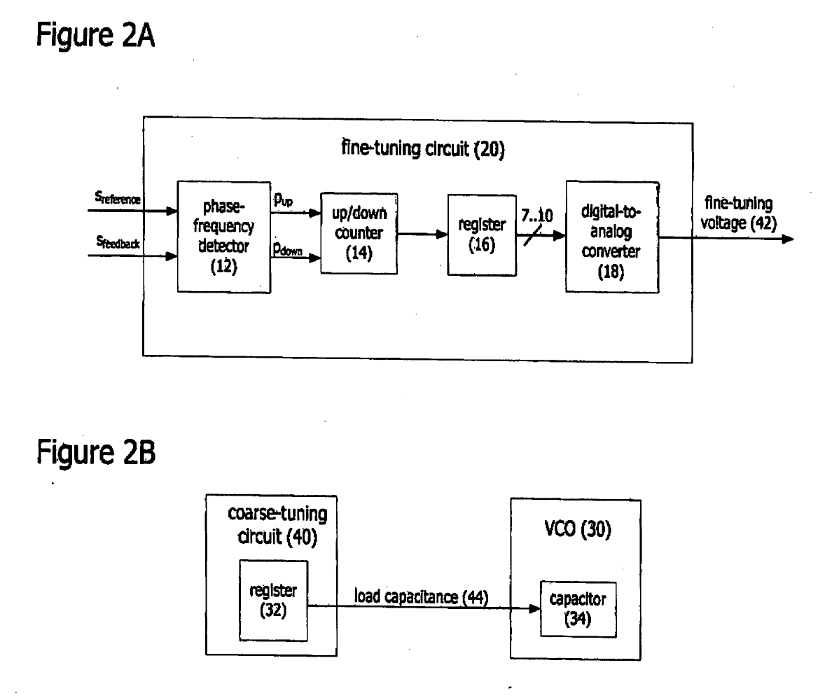

The fine-tuning circuit 20 generates an analog voltage, the fine-tuning voltage 42, to be received by the VCO 30. A block diagram of the fine-tuning circuit 20 is depicted in FIG. 2A, according to some embodiments. The fine-tuning circuit 20 includes a phase-frequency detector (PFD) 12, an up/down counter 14, a register 16, and a digital-to-analog controller (DAC) 18. Alternatively, the fine-tuning circuit 20 may employ a frequency detector in place of the PFD 12. The PFD 12 receives the reference signal, s_{reference}, and the feedback signal, s_{feedback}. Each signal has an associated phase and frequency. Thus, the signal, s_{reference}, has an associated phase, (Preference, and frequency, f_{reference}; the signal, s_{feedback}, has an associated phase, φ_{feeback} and frequency, f_{feedback}. In case of a frequency difference (a difference between f_{reference} and f_{feedback}), the PFD 12 sends either an up pulse (pᵤₚ) or a down pulse (p_{down}) to the up/down counter 14.

The up/down counter 14 counts up or down, depending upon which frequency, f_{reference} or f_{feedback}, is higher. (In some embodiments, the counter 14 is replaced with an infinite impulse response, or IIR, filter.) If an overflow at the up-down counter 14 occurs, the load capacitance 44 is incremented by one by the control logic 26, since a larger capacitance causes the frequency of the VCO 30 to slow down. If an underflow at the up-down counter 14 is detected, the load capacitance 44 is decremented by one by the control logic 26, causing the VCO 30 to speed up.

Following either operation, the fine-tuning recommences. The digital value at the output of the counter 14 is stored in the register 16, and is sent to the DAC 18, which converts the digital signal to an analog voltage, to be received by the VCO 30. Alternatively, the DAC 18 may convert the digital value to a current, which controls the VCO. Because the fine-tuning circuit 20 is part of a feedback loop (FIG. 1), the process may repeat, with a new digital word being stored in the register 16 for each pass of the loop. This iterative process continues until the value in the up-down counter 14 remains between a predetermined upper and lower limit. The optimized fine-tuning value, the fine-tuning voltage 42, is stored in the register 16, such that the VCO 30 may be quickly reinitialized following switching of the clock generator 100. In some embodiments, the fine-tuning voltage 42 is a 7- to 10-bit digital value. After the feedback loop settles, the register 16 contains a digital word that represents the frequency of the oscillator 30.

A block diagram of the coarse-tuning circuit 40 is depicted in FIG. 2B, according to some embodiments. The coarse-tuning circuit 40 includes a register 32 that is coupled to a capacitor 34 within the VCO 30. The coarse-tuning circuit 40 is controlled by the control logic 26 during power-on initialization. By changing the load capacitance 44, the frequency of the VCO 30 changes. A bigger capacitance slows down the VCO 30 relative to a smaller load capacitance value. The coarse-tuning circuit 40 is executed to extend the tuning range of the VCO, to reduce the VCO gain, and to reduce the resolution of the fine-tuning circuit 20. This enables the center frequency of the VCO 30 to be shifted, by varying the charging rate of the capacitor 34 at frequency-sensitive nodes inside the VCO 30.

In some embodiments, the coarse-tuning circuit 40 is executed once during initialization of the clock generator 100. The coarse tuning compensates for any process variation (while the fine tuning addresses temperature and voltage drifts during normal operation). By executing the coarse-tuning circuit 40, the VCO 30 is brought into an operation point near the middle of the voltage-to-frequency characteristic of the clock generator 100. In some embodiments, the coarse-tuning circuit 40 is executed automatically. A capacitance value in the middle of the coarse tuning range is selected. The optimized coarse-tuning value, the load capacitance 44, is stored in the register 32, such that the VCO 30 may be quickly reinitialized following switching of the clock generator 100. In some embodiments, the load capacitance 44 is a 5-bit digital value.

The coarse-tuning circuit 40 thus supplies the load capacitance 44 to the VCO 30 that results in a voltage that is in a broad range near the desired voltage. The fine-tuning circuit 20 supplies a voltage in a narrower range. In some embodiments, once the clock generator 100 has been initialized, the coarse-tuning circuit 40 is no longer activated while the fine-tuning circuit 20 is periodically activated, so as to initiate periodic adjustments of the output frequency, fₒᵤₜ, relative to the input reference frequency, f_{reference}, in order to compensate any voltage and/or temperature drifts that may occur during long disable times of the clock generator 100.

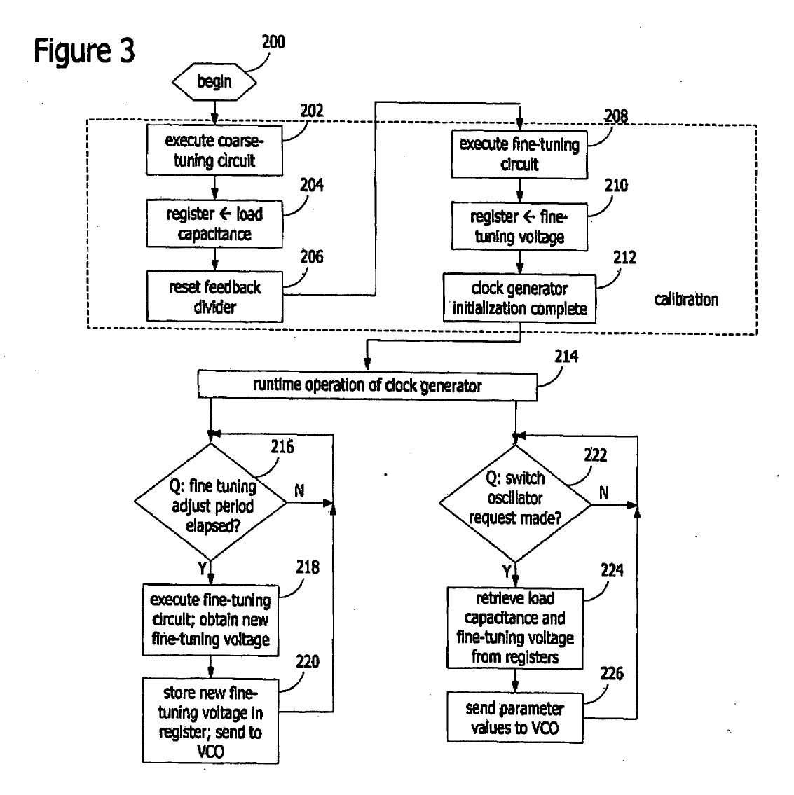

The operation of the clock generator 100 is depicted in the flow diagram of FIG. 3, according to some embodiments. As the clock generator 100 is powered on, several operations take place to calibrate the clock generator 100 (blocks 202-212). The coarse-tuning circuit 40 is executed (block 202), to obtain the load capacitance 44, as described above. The load capacitance 44, in digital form, is sent to the VCO 30, so that a desired oscillation frequency is obtained, within a broad range.

The load capacitance value 44 is stored in the register 32 (block 204). The register 32 may later be accessed to quickly generate the desired output signal, sₒᵤₜ. In some embodiments, the VCO 30 includes several binary-weighted load capacitors in parallel, one or more of which may selectively be switched to the VCO output. The switches are driven by the register 32.

In some embodiments, the fine-tuning circuit 20 is not executed until the feedback divider 24 is reset (block 206). This ensures that a long settling time for phase alignment between the divided clock (s_{feedback}) and the reference clock (s_{reference}) is avoided. Following the reset operation, the fine-tuning circuit 20 is executed (block 208), and a fine-tuning voltage 42 is sent to the VCO 30, to further specify the desired oscillation frequency. The fine-tuning voltage 42 is stored in the register 16 (block 210), for subsequent retrieval, if re-initialization of the VCO 30 occurs. The register 16 may later be accessed to quickly generate the desired output signal, sₒᵤₜ.

Once the coarse-tuning circuit 40 and the fine-tuning circuit 20 have executed a first time, the initialization of the clock generator 100 is complete (block 212). In some embodiments, the calibration (blocks 202-212) is a one-time operation. Following the calibration, the clock generator 100 is in its runtime operation (block 214). During runtime, two independent operations may simultaneously occur, the switch oscillator operation (block 222) and the adjust frequency operation (block 216). In the switch oscillator operation (block 222), the clock generator 100 runs such that the signal produced by the VCO 30, sₒᵤₜ, is at the desired frequency and the clock output, s_{clock}, is stable. The clock generator 100 may be disabled, such as for power savings purposes. The clock generator 100 may be enabled again at any time. Upon request, such as when a system with the clock generator 100 is powered down, the VCO 30 may be disabled. During disablement, the digital values stored in the registers 16 (fine-tuning circuit 20) and 32 (coarse-tuning circuit 40) are not lost, in some embodiments. Subsequently, and again upon request, the oscillator may be enabled.

In the diagram of FIG. 3, once the oscillator 30 is enabled following switching (the “yes” prong of block 222), the calibration sequence is not again executed. This is because during the calibration sequence, the registers (16 and 32) are updated with the fine-tuning and coarse-tuning parameters, respectively, allowing the VCO 30 to be reinitialized very quickly. The fine-tuning voltage 42 (from the register 16) and the load capacitance 44 (from the register 32) are retrieved (block 224) and sent to the VCO 30 (block 226).

As described in FIG. 2A, the fine-tuning voltage 42 is sent to the DAC 18, converted to an analog voltage, and sent to the VCO 30, which controls the VCO frequency. For the load capacitance 44, the register output is connected directly to switches inside the VCO 30, which switch the load capacitors on or off. So, for example, where the register 32 is a 5-bit register, and the register 32 has the value 01001, then two capacitors (the first and the fourth) are selected. Where the capacitor values are binary, say the first capacitor is 1 pico-Farad (pF), the second capacitor is 2 pF, the third capacitor is 4 pF, the fourth capacitor is 8 pF, and the fifth capacitor is 16 pF, the register value 01001 would cause the 1 pF capacitor and the 8 pF capacitor to be turned on, for a total load capacitance of 9 pF to be switched at the VCO output.

The VCO 30 is programmed with the stored values, such that the clock output, sₒᵤₜ, is stabilized quickly. In some embodiments, the clock generator 100 is fully operational (with a stabilized output clock, sₒᵤₜ) within 100 ns of enablement.

In some embodiments, the frequency adjustment routine (block 216) runs separately and in parallel to the switch oscillator operation (block 222). The output signal, sₒᵤₜ, of the oscillator, or, more particularly, the feedback signal, s_{feedback}, is periodically monitored relative to the reference signal, s_{reference}. Temperature and voltage drifts in the system of which the clock generator 100 is a part may cause changes in the output signal, sₒᵤₜ, and the clock signal, s_{clock}. Thus, once a predetermined fine-tuning adjustment period has elapsed (the “yes” prong of block 216), the fine-tuning circuit 20 is executed, resulting in a new fine-tuning voltage 42 (block 218). The new fine-tuning voltage 42 is stored in the register 16 and sent to the VCO 30 (block 220). This will cause the VCO 30 to correct the output voltage, sₒᵤₜ, based on the new fine-tuning voltage. Each time the fine-tuning circuit 20 is executed, a digital representation of the new fine-tuning voltage 42 is stored in the register 16. In some embodiments, the predetermined fine-tuning adjustment period is approximately 10 milliseconds (ms). In other embodiments, the predetermined fine-tuning adjustment period is every second. In yet other embodiments, the predetermined fine-tuning adjustment period is ten seconds. The fine-tuning adjustment period is a parameter that may be selected according to the particular circuit design specifications.

Thus, the load capacitance 44, stored in the register 32, is obtained once while the fine-tuning voltage 42, stored in the register 16, is updated periodically, to compensate for any frequency drift caused by temperature or voltage variations.

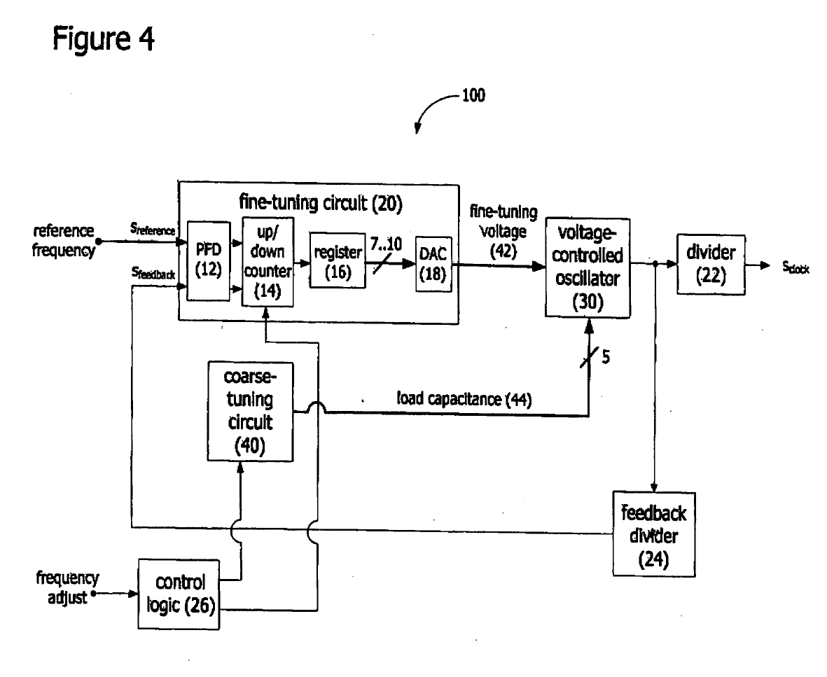

FIG. 4 is a detailed block diagram of the clock generator 100 of FIG. 1, according to some embodiments. The clock generator 100 consists of the VCO 30, the fine-tuning circuit 20, the coarse-tuning circuit 40, a divider 22, a feedback divider 24, and the control logic 26. The VCO 30 may be made up of ring oscillators, inductor-capacitor (LC) oscillators, or some other oscillator configuration. An LC oscillator-based VCO may provide better jitter performance than the ring oscillators. The ring oscillator configuration, however, may be advantageous in terms of area and achievable tuning range. Thus, there exist many applications in which the clock generator 100 may be used.

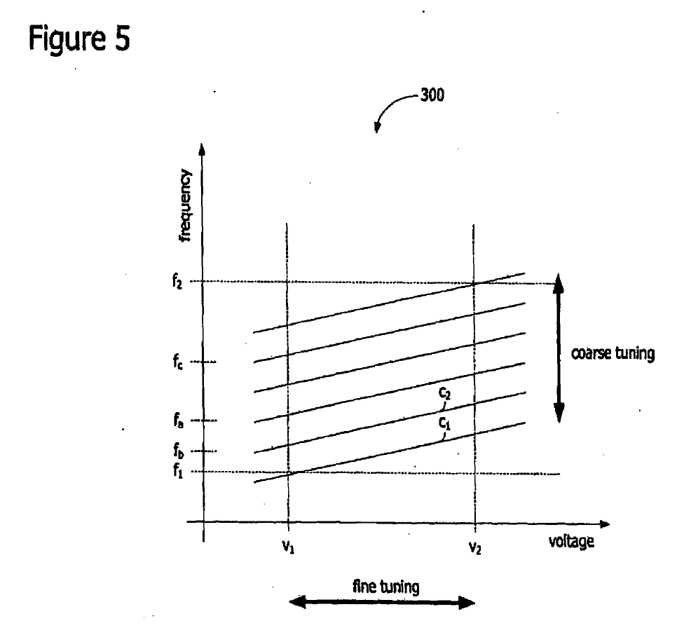

A graph 300 of voltage versus frequency is depicted in FIG. 5, according to some embodiments. The graph 300 depicts the frequency-voltage characteristics of the VCO 30 that enables the fine-tuning circuit 20 and the coarse-tuning circuit 40 to achieve the fast settling times described above. Several parallel curves are depicted in the graph 300. Each curve represents a different capacitance parameter selection. Recall that coarse tuning is achieved by capacitance control. Selecting an appropriate capacitance parameter provides the VCO 30 with a broad range near the desired voltage. Each parallel curve depicted in FIG. 5 represents one broad voltage range. Once one of the curves is selected by the coarse-tuning circuit 40, the frequency of the output signal, sₒᵤₜ, is now coarsely (broadly) determined. In some embodiments, the coarse tuning operation is performed one time during initialization of the clock generator 100.

The fine-tuning of the VCO 30, however, is achieved by voltage control covering a much smaller frequency range. The gain of the VCO 30 is reduced. As described above, fine-tuning is performed periodically, to compensate frequency drifts caused by temperature or voltage variations during operation of the clock generator 100. Thus, while the coarse-tuning selects one of the parallel curves in the graph 300, the fine-tuning operation will select a specific point on the curve.

In some embodiments, the center frequency, f_{c}, of the graph 300 is approximately 5 gigahertz (GHz), while the frequency range (between f₁ and f₂) is 3.5-7 GHz; the voltage range (between v₁ and v₂) is approximately one volt (V). A reasonable tuning range is 500 megahertz (MHz) for a 5 GHz center frequency. This provides a +/−five percent range for compensation of voltage and temperature. The numbers provided herein are merely illustrative of empirical results obtained, and are not meant to limit the possible implementations of the clock generator 100.

The parallel curves of the graph 300 that are selected for coarse tuning overlap significantly. For example, the highest frequency on the curve, c₁, denoted as frequency, fₐ, is a lower frequency than the lowest frequency on the curve, c₂, denoted as frequency, f_{b}. This ensures that the nominal operating point remains in the middle part of the curve, obviating the need to perform coarse-tuning operations more than once. In some embodiments, an overlap of 100% allows using at least 50% of the range for fine-tuning operations, without needing to switch to another coarse-tuning curve.

In some embodiments, the range of each coarse-tuning curve depicted in FIG. 5 covers at least the process variations. As used herein, process variations are parameters, usually related to the manufacture of a circuit, for which precise predictions are unavailable. Such parameters may change for each production lot of a system, for example. While the process variation parameters may not be precisely known, a range of values for the parameter may be ascertainable. Each coarse-tuning curve preferably accounts for the range of values of process variations, so that the coarse-tuning operation may be executed a single time. If the coarse-tuning range is extended such that a factor of two is achieved between the maximum frequency and the minimum frequency, the clock generator 100 becomes more flexible, in some embodiments. In combination with the divider 22 at the clock output, sₒᵤₜ, the clock generator 100 may generate any output frequency below the maximum VCO frequency. This makes the selection of the ratio of the feedback divider 24 and of a VCO curve less sensitive to the VCO center frequency, f_{c}. The VCO center frequency is typically highly dependent on the technology, e.g., from inductances.

In some embodiments, the control loop of the clock generator 100 (the fine-tuning circuit 20, the VCO 30, and the feedback divider 24) has a low bandwidth. This eases the realization of the PFD 12 and the up/down counter 14.

Where an IIR filter is used instead of the up-down counter 14, issues with stability of the clock generator 100 may be addressed by foreseeing an additional proportional path, which bypasses the integral path.

The resolution of the DAC 18 determines the accuracy of the output frequency, fₒᵤₜ. In some embodiments, with a 7-bit resolution of the digital value fed into the DAC 18, the achieved frequency accuracy is ≈1000 parts per million (ppm); with a 10-bit resolution of the digital value, accuracy of ≈100 ppm is achieved. In some embodiments, the DAC 18 is monotonic. One type of monotonic DAC, a thermometer DAC, may be used.

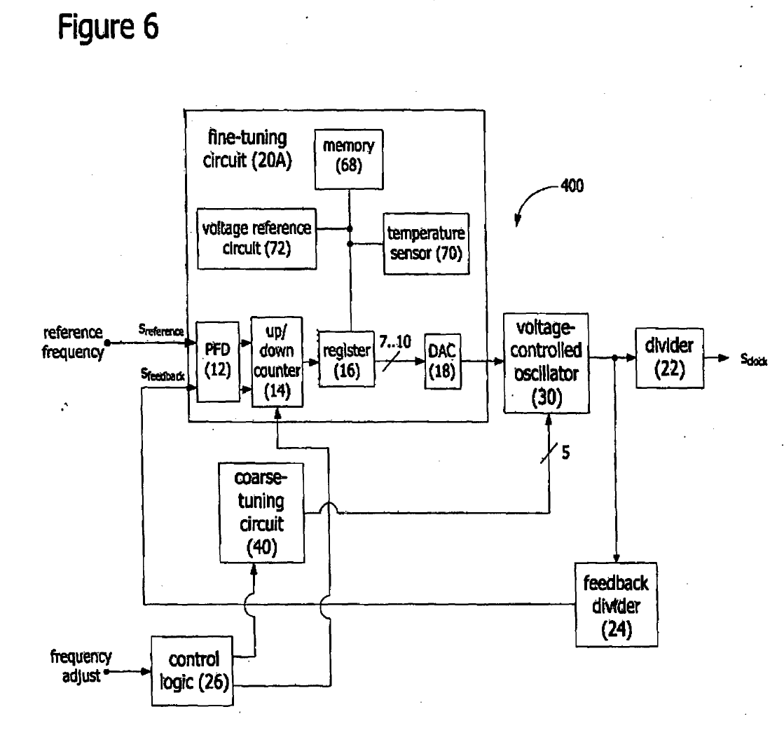

Another clock generator 400 is depicted in FIG. 6, according to some embodiments. In addition to featuring the circuitry of the clock generator 100 (FIGS. 1 and 4), the clock generator 400 includes a modified fine-tuning circuit 20A, with a memory 68, a voltage reference circuit 72, and a temperature sensor 70. The additional circuitry enables the clock generator 400 to obtain the temperature and voltage dependencies during the initial calibration process (FIG. 3), then store them digitally in the register 16. The memory 68 may be a look-up table (LUT) of stored temperature and voltage parameters. Based upon the temperature information obtained by the temperature sensor 70, a value from the memory 68 may be selected for storage in the register 16. In some embodiments, the register 16 is replaced with a multi-dimensional array. A multi-dimensional array may be used to store the state for each temperature and voltage condition. In the clock generator 400, the fine-tuning circuit 20A obtains the appropriate voltage information, not from the PFD 12, but from the LUT in the memory 68 and the temperature sensor 70.

In some embodiments, the clock generator 100 (or the clock generator 400) provides several advantages over other clock generators. For one, a settling time of 100 ns or less may be realized, while prior art clock generators typically take several microseconds (us) to settle (under like operating conditions). Thus, the clock generator 100 (400) has a settling time that is an order of magnitude less than is found with current fast-locking PLLS. The clock generator 100 (400) is also flexible in terms of selectable output frequencies, using the divider 22. Thus, the clock generator 100 (400) may be used in a variety of applications. For the clock generator 100, adjustment to an external crystal-based reference ensures high-frequency accuracy and stability. The process dependency of the VCO 30 may be reduced, as the center frequency, f_{c}, is of less influence than with some clock generators. Proven high-performance VCOs, such as silicon-proven VCOs, optimized for a particular application, may be used, ensuring known jitter performance. Other types of VCOs, such as LC oscillators, may also be used. Thus, the possible implementations of the clock generator 100 are varied.

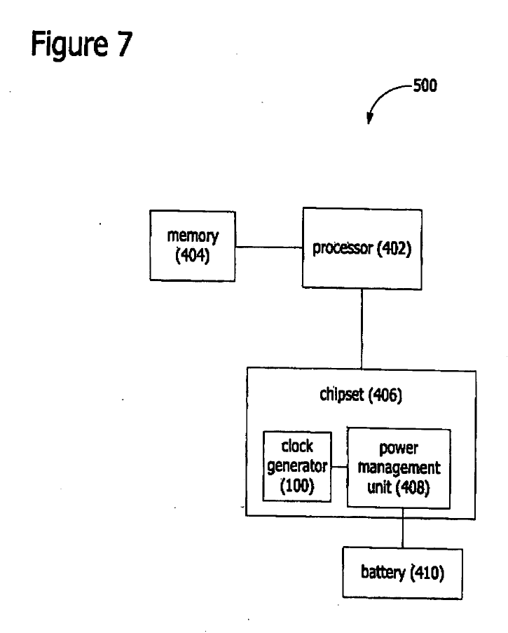

FIG. 7 is a block diagram of a processor-based system 500 using the clock generator 100 of FIG. 1, according to some embodiments. The processor-based system 500 includes a processor 402, a memory 404, and a chipset 406, including the clock generator 100 of FIG. 1 and a power management unit 408. The power management unit 408 may, for example, control power to a battery 410, among its many functions. The clock generator 100 may additionally feed into other CPU and chipset input/output (I/O) PLLs. The short settling time of the clock generator 100 allows flexible on and off switching of the generated clocks for power savings purposes. The clock generator 100 may thus be part of an efficient power management system. For some applications, low power may make the processor-based system 500 competitive in the market.

The clock generator 100 offers a high range of potential frequencies while being less process-dependent regarding such criteria as on-chip inductances. In some embodiments, the clock generator 100 may be implemented without having a very accurate VCO center frequency, f_{c}. This eases the realization in innovative technologies while enabling the clock generator 100 to be readily ported to other technologies.

While the disclosure has been described with respect to a limited number of embodiments, those skilled in the art will appreciate numerous modifications and variations therefrom. It is intended that the appended claims cover all such modifications and variations as fall within the true spirit and scope of the disclosed subject matter.

We claim:

1. A clock generator, comprising:
an oscillator to receive a first parameter and a second parameter, the oscillator to generate a clock signal based on the first parameter and the second parameter, the oscillator comprising a fast settling time;
a coarse-tuning circuit comprising a coarse-tuning register, wherein the coarse-tuning circuit:
generates the first parameter; and
stores the first parameter in the coarse-tuning register;
a fine-tuning circuit comprising a fine-tuning register, wherein the fine-tuning circuit:
generates the second parameter; and
stores the second parameter in the fine-tuning register.

2. The clock generator of claim 1, wherein the first parameter is a digital value corresponding to a load capacitance.

3. The clock generator of claim 2, wherein the second parameter is second digital value corresponding to an analog voltage.

4. The clock generator of claim 3, wherein the fast settling time is one hundred nanoseconds or less.

5. The clock generator of claim 3, the fine-tuning circuit further comprising:
a phase-frequency detector to receive a reference signal and a feedback signal, the phase-frequency detector to generate a pulse; and
a counter to generate the second parameter based upon the pulse.

6. The clock generator of claim 5, the fine-tuning circuit further comprising:
a register to store second parameter; and
a digital-to-analog converter to convert the second parameter to an analog voltage.

7. The clock generator of claim 1, wherein the coarse-tuning circuit is executed one time.

8. The clock generator of claim 1, wherein the fine-tuning circuit is executed periodically.

9. The clock generator of claim 5, further comprising:
a divider to receive an output signal from the oscillator, wherein the divider generates the clock signal based on the output signal; and
a feedback divider to receive the output signal from the oscillator, wherein the feedback signal is based on the output signal.

10. The clock generator of claim 1, further comprising:
control logic coupled to the fine-tuning circuit and the coarse-tuning circuit, wherein the control logic executes the fine-tuning circuit and the coarse-tuning circuit upon receipt of a frequency adjust request.

11. The clock generator of claim 8, wherein the fine-tuning circuit is executed every ten milliseconds.

12. A method, comprising:
calibrating an oscillator, the oscillator to receive a first parameter and a second parameter, the oscillator to generate a clock signal;
disabling the oscillator; and
programming the oscillator using the first parameter and the second parameter when the oscillator is enabled.

13. The method of claim 12, further comprising:
storing the first parameter in a first register, wherein the first parameter remains in the first register when the oscillator is disabled; and
storing the second parameter in a second parameter, wherein the second parameter remains in the second register when the oscillator is disabled.

15. The method of claim 14, further comprising:
obtaining the first parameter once during calibration of the oscillator.

16. The method of claim 14, further comprising:
obtaining the second parameter periodically during operation of the oscillator.

17. The method of claim 16, obtaining the second parameter periodically during operation of the oscillator further comprising obtaining the second parameter every second.

18. A system, comprising:
a processor to execute instructions, a memory to store the instructions; and a chipset, the chipset comprising:
a power management unit to drive a battery; and
a clock generator, comprising:
an oscillator to receive a first parameter and a second parameter, the oscillator to generate a clock signal based on the first parameter and the second parameter, the oscillator comprising a fast settling time;
a coarse-tuning circuit comprising a coarse-tuning register, wherein the coarse-tuning circuit generates the first parameter and stores the first parameter in the coarse-tuning register;
a fine-tuning circuit comprising a fine-tuning register, wherein the fine-tuning circuit generates the second parameter and stores the second parameter in the fine-tuning register.

19. The system of claim 18, the fine-tuning circuit further comprising:
a phase-frequency detector to receive a reference signal and a feedback signal, the phase-frequency detector to generate a pulse; and
a counter to generate the second parameter based upon the pulse.

20. The system of claim 19, wherein the coarse-tuning circuit is executed one time and the fine-tuning circuit is executed periodically.
